(19) United States
(12) Patent Application Publication
(10) Pub. No.: US 2022/0128699 A1
(43) Pub. Date: Apr. 28, 2022

(54) LIDAR SYSTEMS FOR PHONES

(71) Applicant: Shenzhen Genorivision Technology Co. Ltd., Shenzhen (CN)

(72) Inventors: Peiyan CAO, Shenzhen (CN); Yurun LIU, Shenzhen (CN)

(21) Appl. No.: 17/571,989

(22) Filed: Jan. 10, 2022

Related U.S. Application Data
(63) Continuation of application No. PCT/CN2019/098267, filed on Jul. 30, 2019.

(51) Int. Cl. G01S 17/894; G01S 7/481; G01S 7/4865; G10K 15/04; H04N 5/225

(52) U.S. Cl. CPC G01S 17/894; G01S 7/4816; H04N 5/2256; G10K 15/04; G01S 7/4865

(57) ABSTRACT

Disclosed herein is a phone, comprising a Lidar system which comprises (A) an image sensor comprising an array of avalanche photodiodes (APDs)(i), i=1, . . . , N, for i=1, . . . , N, the APD (i) comprising an absorption region (i) and an amplification region (i), wherein the absorption region (i) is configured to generate charge carriers from a photon absorbed by the absorption region (i), wherein the amplification region (i) comprises a junction (i) with a junction electric field (i) in the junction (i), wherein the junction electric field (i) is at a value sufficient to cause an avalanche of charge carriers entering the amplification region (i), but not sufficient to make the avalanche self-sustaining, and wherein the junctions (i), i=1, . . . , N are discrete, and (B) a radiation source, wherein the phone is configured to convert sounds to electrical signals, reproduce sounds from electrical signals, and send/receive electrical signals to/from another phone via any means.

### TECHNICAL FIELD

The disclosure herein relates Lidar (Light Detection and Ranging) systems for phones.

### BACKGROUND

An image sensor or imaging sensor is a sensor that can detect a spatial intensity distribution of a radiation. An image sensor usually represents the detected image by electrical signals. Image sensors based on semiconductor devices may be classified into several types, including semiconductor charge-coupled devices (CCD), complementary metal-oxide-semiconductor (CMOS), N-type metal-oxide-semiconductor (NMOS).

A CMOS image sensor is a type of active pixel sensor made using the CMOS semiconductor process. Light incident on a pixel in the CMOS image sensor is converted into an electric voltage. The electric voltage is digitized into a discrete value that represents the intensity of the light incident on that pixel. An active-pixel sensor (APS) is an image sensor that includes pixels with a photodetector and an active amplifier.

A CCD image sensor includes a capacitor in a pixel. When light incidents on the pixel, the light generates electrical charges and the charges are stored on the capacitor. The stored charges are converted to an electric voltage and the electrical voltage is digitized into a discrete value that represents the intensity of the light incident on that pixel.

In addition to being used for capturing 2D images of objects (i.e., for detecting a spatial intensity distribution of an incoming radiation) as mentioned above, an image sensor can also be used in a Lidar (Light Detection and Ranging) system for capturing 3D images of objects (i.e., for detecting a spatial distance distribution of incoming radiation).

### SUMMARY

Disclosed herein is a phone, comprising a Lidar system which comprises (a) an image sensor comprising an array of avalanche photodiodes (APDs)(i), i=1, . . . , N, N being a positive integer, for i=1, . . . , N, the APD (i) comprising an absorption region (i) and an amplification region (i), wherein the absorption region (i) is configured to generate charge carriers from a photon absorbed by the absorption region (i), wherein the amplification region (i) comprises a junction (i) with a junction electric field (i) in the junction (i), wherein the junction electric field (i) is at a value sufficient to cause an avalanche of charge carriers entering the amplification region (i), but not sufficient to make the avalanche self-sustaining, and wherein the junctions (i), i=1, . . . , N are discrete, and (b) a radiation source, wherein the radiation source is configured to emit a pulse of illumination photons at a time point Ta; wherein for i=1, . . . , N, the Lidar system is configured to measure a time of flight (i) from Ta to a time point Tb(i) at which a photon of the illumination photons returns to the APD (i) after bouncing off an object surface spot (i) in a sub-field of view (i) of the Lidar system corresponding to the APD (i), wherein for i=1, . . . , N, based on the time of flight (i), the Lidar system is configured to determine a spot distance (i) from the Lidar system to the object surface spot (i), wherein the phone is configured to convert sounds to electrical signals, wherein the phone is configured to reproduce sounds from electrical signals, wherein the phone is configured to send electrical signals to another phone via wire, radio signal, the internet, electromagnetic wave, or any combinations thereof, and wherein the phone is configured to receive electrical signals from another phone via wire, radio signal, the internet, electromagnetic wave, or any combinations thereof.

According to an embodiment, the phone is configured to browse the Web.

According to an embodiment, N is greater than 1.

According to an embodiment, the illumination photons comprise infrared photons, and for i=1, . . . , N, the APD (i) comprises silicon.

According to an embodiment, for i=1, . . . , N, the absorption region (i) has a thickness of 10 microns or above.

According to an embodiment, for i=1, . . . , N, an absorption region electric field (i) in the absorption region (i) is not high enough to cause avalanche effect in the absorption region (i).

According to an embodiment, for i=1, . . . , N, the absorption region (i) is an intrinsic semiconductor or a semiconductor with a doping level less than 10¹² dopants/cm³.

According to an embodiment, N>1, and at least some absorption regions of the absorption regions (i), i=1, . . . , N are joined together.

According to an embodiment, for i=1, . . . , N, the APD (i) further comprises an amplification region (i′) such that the amplification region (i) and the amplification region (i′) are on opposite sides of the absorption region (i).

According to an embodiment, the amplification regions (i), i=1, . . . , N are discrete.

According to an embodiment, for i=1, . . . , N, the junction (i) is a p-n junction or a heterojunction.

According to an embodiment, for i=1, . . . , N, the junction (i) comprises a first layer (i) and a second layer (i), and for i=1, . . . , N, the first layer (i) is a doped semiconductor and the second layer (i) is a heavily doped semiconductor.

According to an embodiment, for i=1, . . . , N, the junction (i) further comprises a third layer (i) sandwiched between the first layer (i) and the second layer (i), and for i=1, . . . , N, the third layer (i) comprises an intrinsic semiconductor.

According to an embodiment, N>1, and at least some third layers of the third layers (i), i=1, . . . , N, are joined together.

According to an embodiment, for i=1, . . . , N, the first layer (i) has a doping level of 10¹³ to 10¹⁷ dopants/cm³.

According to an embodiment, N>1, and at least some first layers of the first layers (i), i=1, . . . , N are joined together.

According to an embodiment, the image sensor further comprises electrodes (i), i=1, . . . , N in electrical contact with the second layers (i), i=1, . . . , N, respectively.

According to an embodiment, the image sensor further comprises a passivation material configured to passivate a surface of the absorption regions (i), i=1, . . . , N.

According to an embodiment, the image sensor further comprises a common electrode electrically connected to the absorption regions (i), i=1, . . . , N.

According to an embodiment, for i=1, . . . , N, the junction (i) is separated from a junction of a neighbor junction by (a) a material of the absorption region (i), (b) a material of the first layer (i) or of the second layer (i), (c) an insulator material, or (d) a guard ring (i) of a doped semiconductor.

According to an embodiment, for i=1, . . . , N, the guard ring (i) is a doped semiconductor of a same doping type as the second layer (i), and for i=1, . . . , N, the guard ring (i) is not heavily doped.

Disclosed herein is a method of operating a phone comprising a Lidar system which comprises (a) an image sensor comprising an array of avalanche photodiodes (APDs)(i), i=1, . . . , N, N being a positive integer, for i=1, . . . , N, the APD (i) comprising an absorption region (i) and an amplification region (i), wherein the absorption region (i) is configured to generate charge carriers from a photon absorbed by the absorption region (i), wherein the amplification region (i) comprises a junction (i) with a junction electric field (i) in the junction (i), wherein the junction electric field (i) is at a value sufficient to cause an avalanche of charge carriers entering the amplification region (i), but not sufficient to make the avalanche self-sustaining, and wherein the junctions (i), i=1, . . . , N are discrete, and (b) a radiation source, the method comprising: emitting a pulse of illumination photons at a time point Ta using the radiation source; for i=1, . . . , N, measuring a time of flight (i) from Ta to a time point Tb(i) at which a photon of the illumination photons returns to the APD (i) after bouncing off an object surface spot (i) in a sub-field of view (i) of the Lidar system corresponding to the APD (i); and for i=1, . . . , N, determining a spot distance (i) from the Lidar system to the object surface spot (i) based on the time of flight (i), wherein the phone is configured to convert sounds to electrical signals, wherein the phone is configured to reproduce sounds from electrical signals, wherein the phone is configured to send electrical signals to another phone via wire, radio signal, the internet, electromagnetic wave, or any combinations thereof, and wherein the phone is configured to receive electrical signals from another phone via wire, radio signal, the internet, electromagnetic wave, or any combinations thereof.

According to an embodiment, the method further comprises performing said emitting, said measuring, and said determining multiple times thereby capturing a video of spatial distance distribution of surrounding scenes.

According to an embodiment, the phone is configured to browse the Web.

According to an embodiment, N is greater than 1.

According to an embodiment, the illumination photons comprise infrared photons, and for i=1, . . . , N, the APD (i) comprises silicon.

According to an embodiment, for i=1, . . . , N, the absorption region (i) has a thickness of 10 microns or above.

According to an embodiment, for i=1, . . . , N, an absorption region electric field (i) in the absorption region (i) is not high enough to cause avalanche effect in the absorption region (i).

According to an embodiment, for i=1, . . . , N, the absorption region (i) is an intrinsic semiconductor or a semiconductor with a doping level less than 10¹² dopants/cm³.

According to an embodiment, N>1, and at least some absorption regions of the absorption regions (i), i=1, . . . , N are joined together.

According to an embodiment, for i=1, . . . , N, the APD (i) further comprises an amplification region (i′) such that the amplification region (i) and the amplification region (i′) are on opposite sides of the absorption region (i).

According to an embodiment, the amplification regions (i), i=1, . . . , N are discrete.

According to an embodiment, for i=1, . . . , N, the junction (i) is a p-n junction or a heterojunction.

According to an embodiment, for i=1, . . . , N, the junction (i) comprises a first layer (i) and a second layer (i), and for i=1, . . . , N, the first layer (i) is a doped semiconductor and the second layer (i) is a heavily doped semiconductor.

According to an embodiment, for i=1, . . . , N, the junction (i) further comprises a third layer (i) sandwiched between the first layer (i) and the second layer (i), and for i=1, . . . , N, the third layer (i) comprises an intrinsic semiconductor.

According to an embodiment, N>1, and at least some third layers of the third layers (i), i=1, . . . , N, are joined together.

According to an embodiment, for i=1, . . . , N, the first layer (i) has a doping level of 10¹³ to 10¹⁷ dopants/cm³.

According to an embodiment, N>1, and at least some first layers of the first layers (i), i=1, . . . , N are joined together.

According to an embodiment, the image sensor further comprises electrodes (i), i=1, . . . , N in electrical contact with the second layers (i), i=1, . . . , N, respectively.

According to an embodiment, the image sensor further comprises a passivation material configured to passivate a surface of the absorption regions (i), i=1, . . . , N.

According to an embodiment, the image sensor further comprises a common electrode electrically connected to the absorption regions (i), i=1, . . . , N.

According to an embodiment, for i=1, . . . , N, the junction (i) is separated from a junction of a neighbor junction by (a) a material of the absorption region (i), (b) a material of the first layer (i) or of the second layer (i), (c) an insulator material, or (d) a guard ring (i) of a doped semiconductor.

According to an embodiment, for i=1, . . . , N, the guard ring (i) is a doped semiconductor of a same doping type as the second layer (i), and for i=1, . . . , N, the guard ring (i) is not heavily doped.

### BRIEF DESCRIPTION OF FIGURES

FIG. 1 schematically shows the electric current in an APD as a function of the intensity of light incident on the APD when the APD is in the linear mode, and a function of the intensity of light incident on the APD when the APD is in the Geiger mode.

FIG. 2A, FIG. 2B and FIG. 2C schematically show the operation of an APD, according to an embodiment.

FIG. 3A schematically shows a cross section of an image sensor based on an array of APDs.

FIG. 3B shows a variant of the image sensor of FIG. 3A.

FIG. 3C shows a variant of the image sensor of FIG. 3A.

FIG. 3D shows a variant of the image sensor of FIG. 3A.

FIG. 4A-FIG. 4H schematically show a method of making the image sensor.

FIG. 5 schematically shows a Lidar system, according to an embodiment.

FIG. 6 schematically shows a phone including the Lidar system, according to an embodiment.

### DETAILED DESCRIPTION

An avalanche photodiode (APD) is a photodiode that uses the avalanche effect to generate an electric current upon exposure to light. The avalanche effect is a process where free charge carriers in a material are subjected to strong acceleration by an electric field and subsequently collide with other atoms of the material, thereby ionizing them (impact ionization) and releasing additional charge carriers which accelerate and collide with further atoms, releasing more charge carriers—a chain reaction.

Impact ionization is a process in a material by which one energetic charge carrier can lose energy by the creation of other charge carriers. For example, in semiconductors, an electron (or hole) with enough kinetic energy can knock a bound electron out of its bound state (in the valence band) and promote it to a state in the conduction band, creating an electron-hole pair.

An APD may work in the Geiger mode or the linear mode. When the APD works in the Geiger mode, it may be called a single-photon avalanche diode (SPAD) (also known as a Geiger-mode APD or G-APD). A SPAD is an APD working under a reverse bias above the breakdown voltage. Here the word “above” means that absolute value of the reverse bias is greater than the absolute value of the breakdown voltage.

A SPAD may be used to detect low intensity light (e.g., down to a single photon) and to signal the arrival times of the photons with a jitter of a few tens of picoseconds. A SPAD may be in a form of a p-n junction under a reverse bias (i.e., the p-type region of the p-n junction is biased at a lower electric potential than the n-type region) above the breakdown voltage of the p-n junction. The breakdown voltage of a p-n junction is a reverse bias, above which exponential increase in the electric current in the p-n junction occurs.

An APD may work in linear mode. An APD working at a reverse bias below the breakdown voltage is operating in the linear mode because the electric current in the APD is proportional to the intensity of the light incident on the APD.

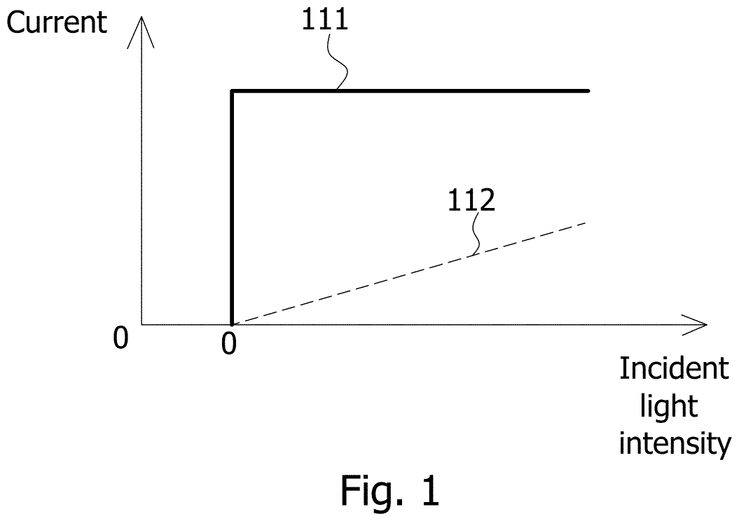

FIG. 1 schematically shows the electric current in an APD as a function 112 of the intensity of light incident on the APD when the APD is in the linear mode, and a function 111 of the intensity of light incident on the APD when the APD is in the Geiger mode (i.e., when the APD is a SPAD). In the Geiger mode, the current shows a very sharp increase with the intensity of the light and then saturation. In the linear mode, the current is essentially proportional to the intensity of the incident light.

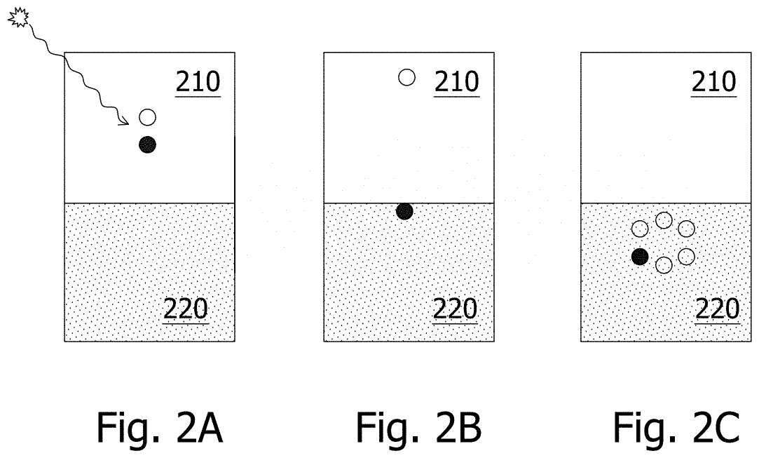

FIG. 2A, FIG. 2B and FIG. 2C schematically show the operation of an APD, according to an embodiment. FIG. 2A shows that when a photon (e.g., an X-ray photon) is absorbed by an absorption region 210 of the APD, multiple (100 to 10000 for an X-ray photon) electron-hole pairs may be generated. However, for simplicity, only one electron-hole pair is shown. The absorption region 210 has a sufficient thickness and thus a sufficient absorptance (e.g., >80% or >90%) for the incident photon. For soft X-ray photons, the absorption region 210 may be a silicon layer with a thickness of 10 microns or above. The electric field in the absorption region 210 is not high enough to cause avalanche effect in the absorption region 210.

FIG. 2B shows that the electrons and holes drift in opposite directions in the absorption region 210. FIG. 2C shows that avalanche effect occurs in an amplification region 220 when the electrons (or the holes) enter that amplification region 220, thereby generating more electrons and holes. The electric field in the amplification region 220 is high enough to cause an avalanche of charge carriers entering the amplification region 220 but not too high to make the avalanche effect self-sustaining. A self-sustaining avalanche is an avalanche that persists after the external triggers disappear, such as photons incident on the APD or charge carriers drifted into the APD.

The electric field in the amplification region 220 may be a result of a doping profile in the amplification region 220. For example, the amplification region 220 may include a p-n junction or a heterojunction that has an electric field in its depletion zone. The threshold electric field for the avalanche effect (i.e., the electric field above which the avalanche effect occurs and below which the avalanche effect does not occur) is a property of the material of the amplification region 220. The amplification region 220 may be on one or two opposite sides of the absorption region 210.

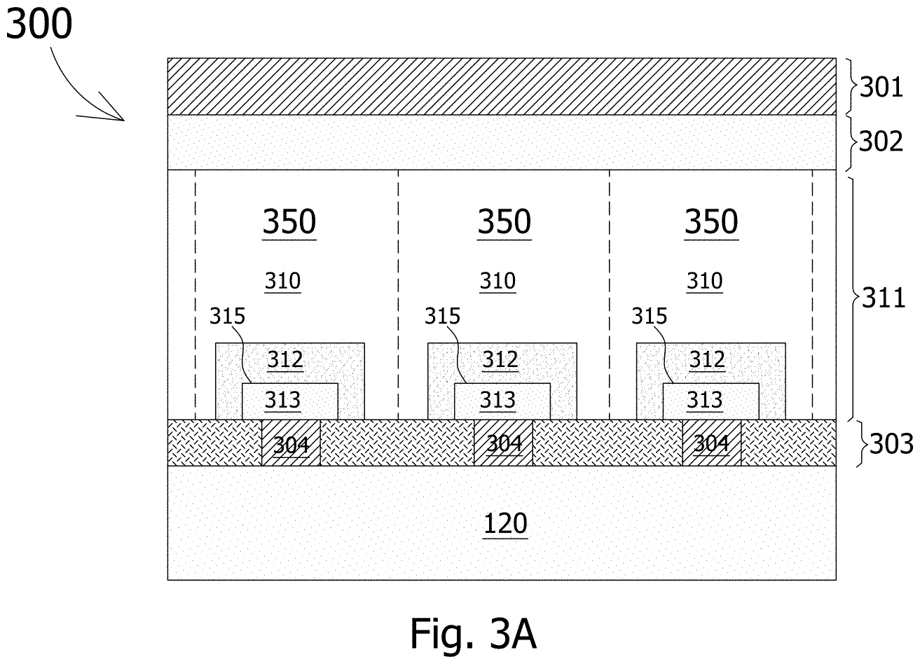

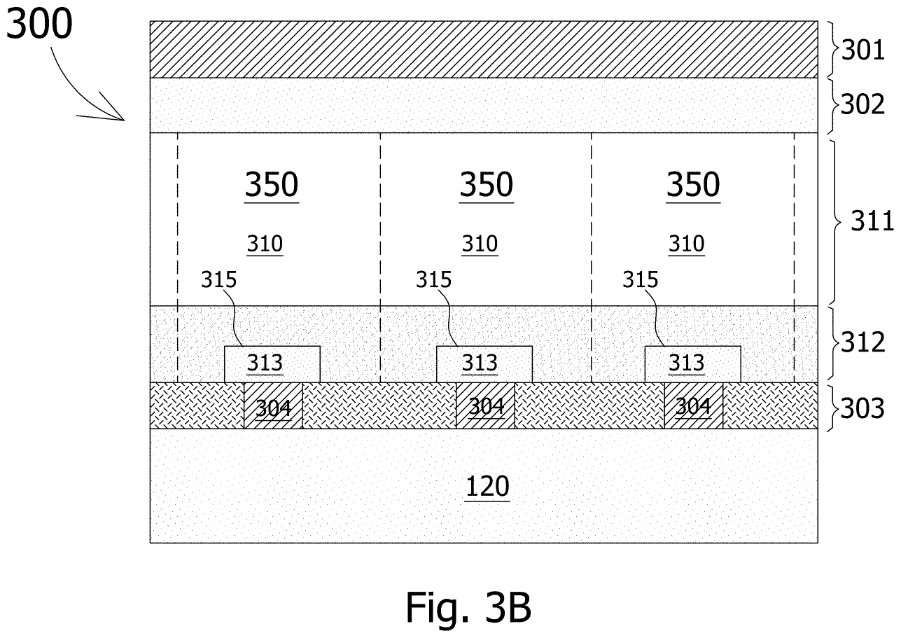

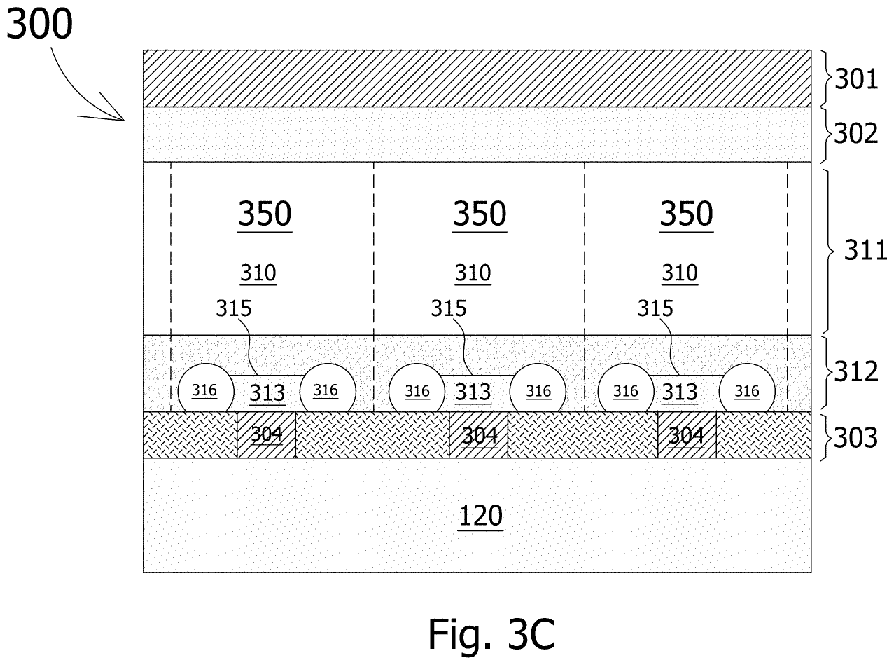

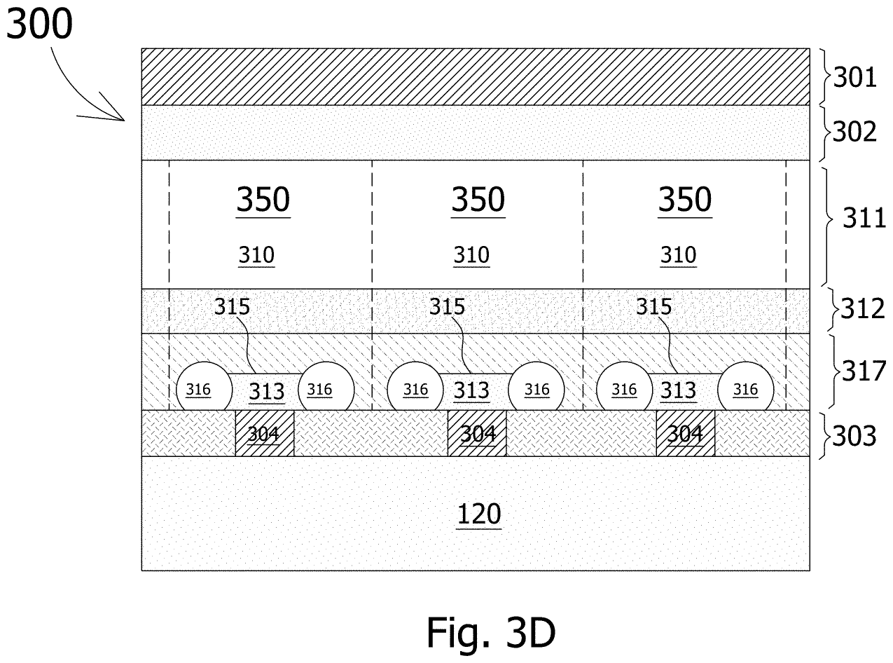

FIG. 3A schematically shows a cross section of an image sensor 300 based on an array of APDs 350. Each of the APDs 350 may have an absorption region 310 and an amplification region 312+313 as the example shown in FIG. 2A, FIG. 2B and FIG. 2C. At least some, or all, of the APDs 350 in the image sensor 300 may have their absorption regions 310 joined together. Namely, the image sensor 300 may have joined absorption regions 310 in a form of an absorption layer 311 that is shared among at least some or all of the APDs 350.

The amplification regions 312+313 of the APDs 350 are discrete regions. Namely the amplification regions 312+313 of the APDs 350 are not joined together. In an embodiment, the absorption layer 311 may be in form of a semiconductor wafer such as a silicon wafer. The absorption regions 310 may be an intrinsic semiconductor or very lightly doped semiconductor (e.g., <10¹² dopants/cm³, <10¹¹ dopants/cm³, <10¹⁰ dopants/cm³, <10⁹ dopants/cm³), with a sufficient thickness and thus a sufficient absorptance (e.g., >80% or >90%) for incident photons of interest (e.g., X-ray photons).

The amplification regions 312+313 may have a junction 315 formed by at least two layers 312 and 313. The junction 315 may be a heterojunction of a p-n junction. In an embodiment, the layer 312 is a p-type semiconductor (e.g., silicon) and the layer 313 is a heavily doped n-type layer (e.g., silicon). The phrase “heavily doped” is not a term of degree. A heavily doped semiconductor has its electrical conductivity comparable to metals and exhibits essentially linear positive thermal coefficient. In a heavily doped semiconductor, the dopant energy levels are merged into an energy band. A heavily doped semiconductor is also called degenerate semiconductor.

The layer 312 may have a doping level of 10¹³ to 10¹⁷ dopants/cm³. The layer 313 may have a doping level of 10¹⁸ dopants/cm³ or above. The layers 312 and 313 may be formed by epitaxy growth, dopant implantation or dopant diffusion. The band structures and doping levels of the layers 312 and 313 can be selected such that the depletion zone electric field of the junction 315 is greater than the threshold electric field for the avalanche effect for electrons (or for holes) in the materials of the layers 312 and 313, but is not too high to cause self-sustaining avalanche. Namely, the depletion zone electric field of the junction 315 should cause avalanche when there are incident photons in the absorption region 310 but the avalanche should cease without further incident photons in the absorption region 310.

The image sensor 300 may further include electrodes 304 respectively in electrical contact with the layer 313 of the APDs 350. The electrodes 304 are configured to collect electric current flowing through the APDs 350. The image sensor 300 may further include a passivation material 303 configured to passivate surfaces of the absorption regions 310 and the layer 313 of the APDs 350 to reduce recombination at these surfaces.

The image sensor 300 may further include an electronics layer 120 which may include an electronic system electrically connected to the electrodes 304. The electronic system is suitable for processing or interpreting electrical signals (i.e., the charge carriers) generated in the APDs 350 by the radiation incident on the absorption regions 310. The electronic system may include an analog circuitry such as a filter network, amplifiers, integrators, and comparators, or a digital circuitry such as a microprocessor, and memory. The electronic system may include one or more analog-to-digital converters.

The image sensor 300 may further include a heavily doped layer 302 disposed on the absorption regions 310 opposite to the amplification regions 312+313, and a common electrode 301 on the heavily doped layer 302. The common electrode 301 of at least some or all of the APDs 350 may be joined together. The heavily doped layer 302 of at least some or all of the APDs 350 may be joined together.

When a photon incidents on the image sensor 300, it may be absorbed by the absorption region 310 of one of the APDs 350, and charge carriers may be generated in the absorption region 310 as a result. One type (electrons or holes) of the charge carriers drift toward the amplification region 312+313 of that one APD. When the charge carriers enter the amplification region 312+313, the avalanche effect occurs and causes amplification of the charge carriers. The amplified charge carriers may be collected by the electronics layer 120 through the electrode 304 of that one APD, as an electric current.

When that one APD is in the linear mode, the electric current is proportional to the number of incident photons in the absorption region 310 per unit time (i.e., proportional to the light intensity at that one APD). The electric currents at the APDs may be compiled to represent a spatial intensity distribution of light, i.e., a 2D image. The amplified charge carriers may alternatively be collected through the electrode 304 of that one APD, and the number of photons may be determined from the charge carriers (e.g., by using the temporal characteristics of the electric current).

The junctions 315 of the APDs 350 should be discrete, i.e., the junction 315 of one of the APDs should not be joined with the junction 315 of another one of the APDs. Charge carriers amplified at one of the junctions 315 of the APDs 350 should not be shared with another of the junctions 315.

The junction 315 of one of the APDs may be separated from the junction 315 of the neighboring APDs (a) by the material of the absorption region wrapping around the junction, (b) by the material of the layer 312 or 313 wrapping around the junction, (c) by an insulator material wrapping around the junction, or (d) by a guard ring of a doped semiconductor.

As shown in FIG. 3A, the layer 312 of each of the APDs 350 may be discrete, i.e., not joined with the layer 312 of another one of the APDs; the layer 313 of each of the APDs 350 may be discrete, i.e., not joined with the layer 313 of another one of the APDs. FIG. 3B shows a variant of the image sensor 300, where the layers 312 of some or all of the APDs are joined together.

FIG. 3C shows a variant of the image sensor 300, where the junction 315 is surrounded by a guard ring 316. The guard ring 316 may be an insulator material or a doped semiconductor. For example, when the layer 313 is heavily doped n-type semiconductor, the guard ring 316 may be n-type semiconductor of the same material as the layer 313 but not heavily doped. The guard ring 316 may be present in the image sensor 300 shown in FIG. 3A or FIG. 3B.

FIG. 3D shows a variant of the image sensor 300, where the junction 315 has an intrinsic semiconductor layer 317 sandwiched between the layer 312 and 313. The intrinsic semiconductor layer 317 in each of the APDs 350 may be discrete, i.e., not joined with other intrinsic semiconductor layer 317 of another APD. The intrinsic semiconductor layers 317 of some or all of the APDs 350 may be joined together.

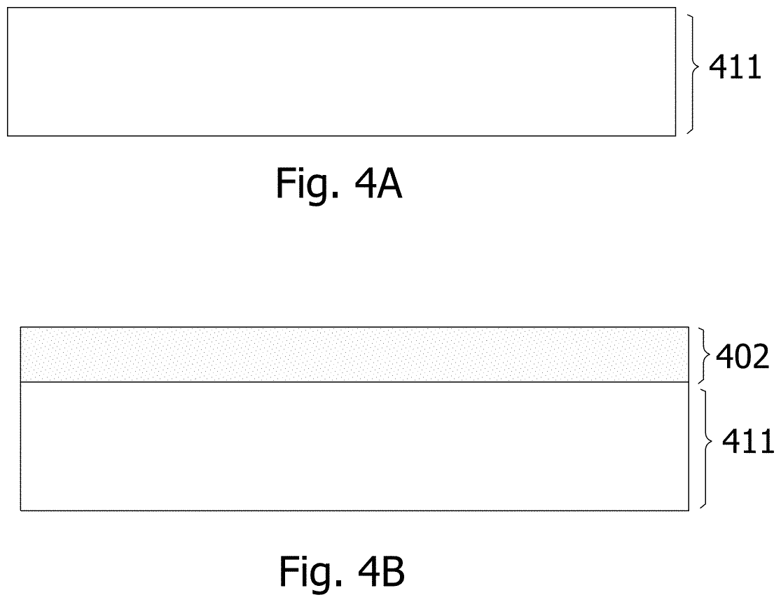

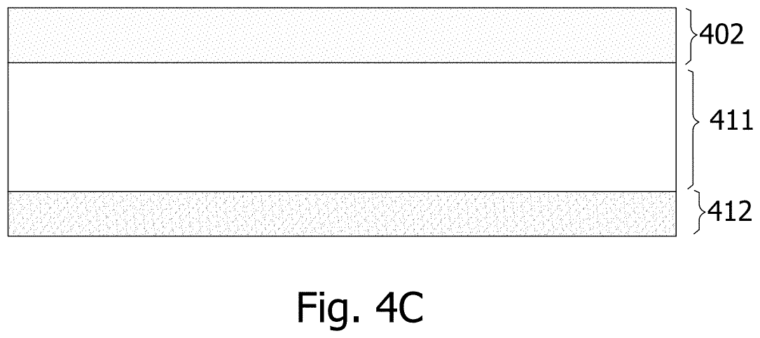

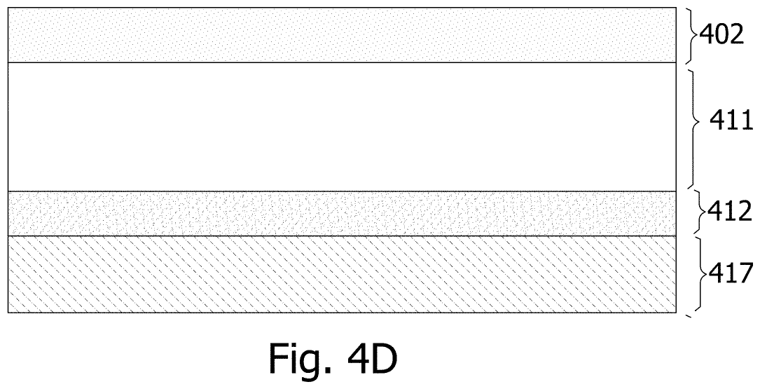

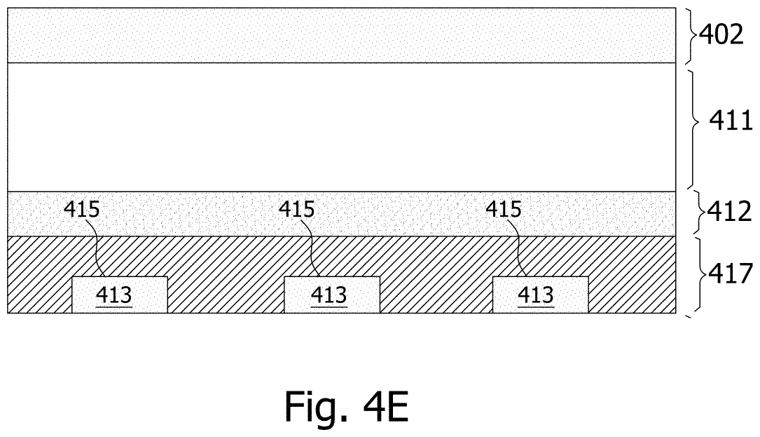

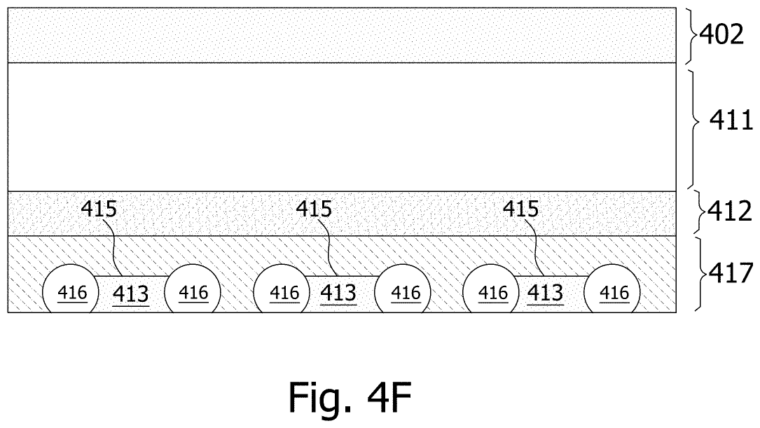

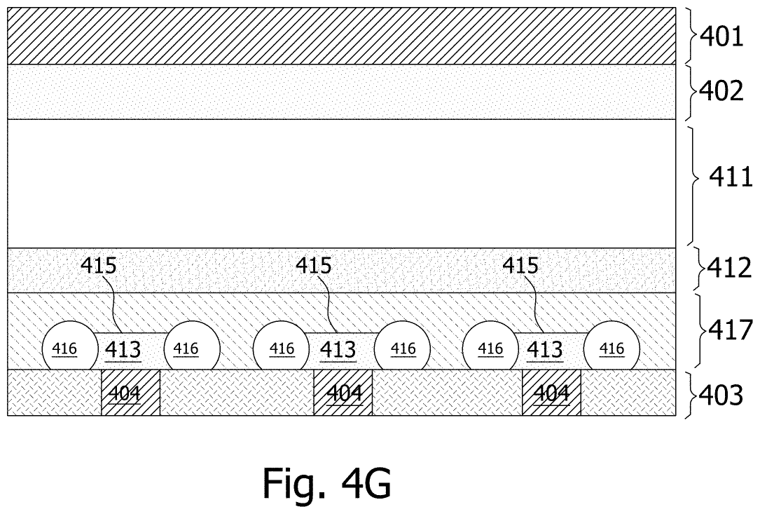

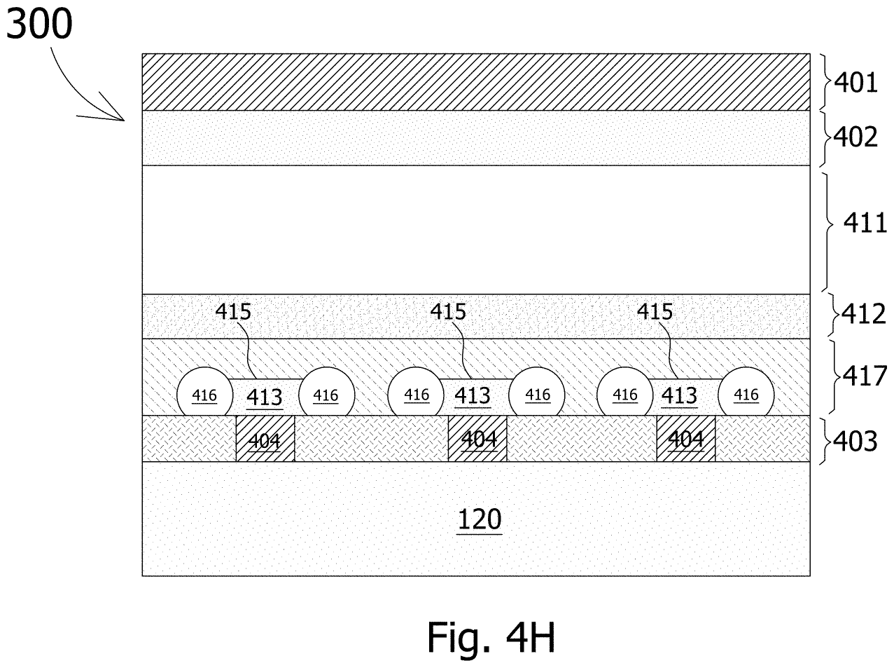

FIG. 4A-FIG. 4H schematically show a method of making the image sensor 300. The method may start with obtaining a semiconductor substrate 411 (FIG. 4A). The semiconductor substrate 411 may be a silicon substrate. The semiconductor substrate 411 is an intrinsic semiconductor or very lightly doped semiconductor (e.g., <10¹² dopants/cm³, <10¹¹ dopants/cm³, <10¹⁰ dopants/cm³, <10⁹ dopants/cm³), with a sufficient thickness and thus a sufficient absorptance (e.g., >80% or >90%) for incident photons of interest (e.g., X-ray photons).

A heavily doped layer 402 (FIG. 4B) is formed on one side of the semiconductor substrate 411. The heavily doped layer 402 (e.g., heavily doped p-type layer) may be formed for diffusing or implanting a suitable dopant into the substrate 411.

A doped layer 412 (FIG. 4C) is formed on the side of the semiconductor substrate 411 opposite to the heavily doped layer 402. The layer 412 may have a doping level of 10¹³ to 10¹⁷ dopants/cm³. The layer 412 may be the same (i.e., the layer 412 is p-type if the layer 402 is p-type and the layer 412 is n-type if the layer 402 is n-type) doping type as the heavily doped layer 402. The layer 412 may be formed by diffusing or implanting a suitable dopant into the substrate 411 or by epitaxy growth. The layer 412 may be a continuous layer or may have discrete areas.

An optional layer 417 (FIG. 4D) may be formed on the layer 412. The layer 417 may be completely separated from the material of the substrate 411 by the layer 412. Namely, if the layer 412 has discrete regions, the layer 417 has discrete regions. The layer 417 is an intrinsic semiconductor. The layer 417 may be formed by epitaxy growth.

A layer 413 (FIG. 4E) is formed on the layer 417 if it is present, or on the layer 412 if the layer 417 is not present. The layer 413 may be completely separated from the material of the substrate 411 by the layer 412 or the layer 417. The layer 413 may have discrete areas. The layer 413 is a heavily doped semiconductor having the opposite (i.e., the layer 413 is n-type if the layer 412 is p-type; the layer 413 is p-type if the layer 412 is n-type) type of dopant as the layer 412. The layer 413 may have a doping level of 10¹⁸ dopants/cm³ or above.

The layer 413 may be formed by diffusing or implanting a suitable dopant into the substrate 411 or by epitaxy growth. The layer 413, the layer 412, and the layer 417 if present, form discrete junctions 415 (e.g., p-n junctions, p-i-n junctions, hetero junctions).

Optional guard rings 416 (FIG. 4F) may be formed around the junctions 415. The guard ring 416 may be a semiconductor of the same doping type as the layer 413 but not heavily doped.

A passivation material 403 (FIG. 4G) may be applied to passivate surfaces of the substrate 411, the layers 412 and 413. Electrodes 404 may be formed and electrically connected to the junctions 415 through the layer 413. A common electrode 401 may be formed on the heavily doped layer 402 for electrical connection thereto.

An electronics layer 120 (FIG. 4H) on a separate substrate may be bonded to the structure of FIG. 4G such that the electronic system in the electronics layer 120 becomes electrically connected to the electrodes 404, resulting in the image sensor 300.

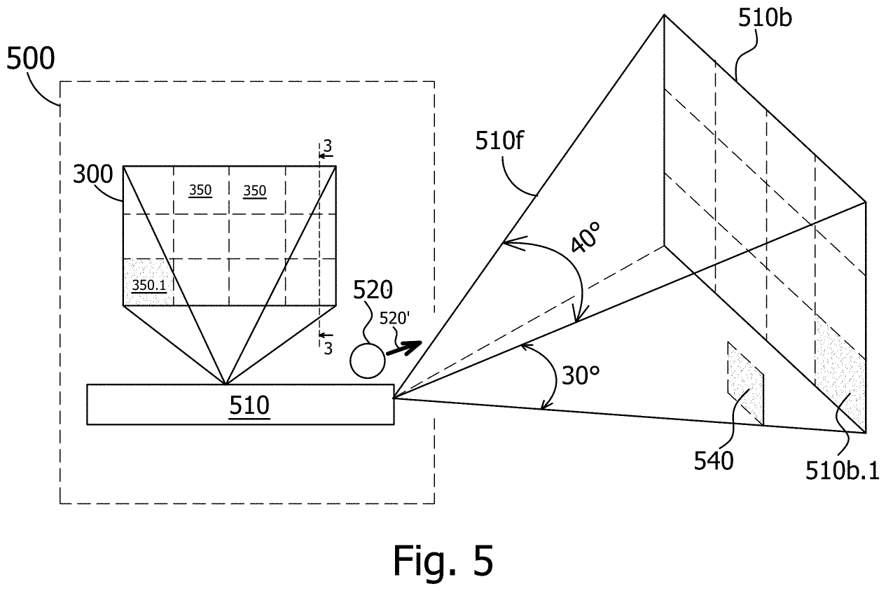

A top down view of the image sensor 300 of FIGS. 3A, 3B, 3C, and 3D is shown in FIG. 5, in an embodiment. Specifically, with reference to FIG. 5, the image sensor 300 may include 12 APDs 350 arranged in a rectangular array of 3 rows and 4 columns. It should be noted that FIGS. 3A, 3B, 3C, and 3D are 4 cross sectional views of the image sensor 300 of FIG. 5 along a line 3-3 according to different embodiments. In general, the image sensor 300 may include any number of APDs 350 arranged in any way.

FIG. 5 schematically shows a Lidar (Light Detection and Ranging) system 500, in an embodiment. The Lidar system 500 may include the image sensor 300, an optical system 510, and a radiation source 520 electrically connected to the image sensor 300. The Lidar system 500 may be used for capturing 3D (3 dimension) images (also referred to as range images) of objects such as human faces, people, chairs, etc.

In an embodiment, the operation of the Lidar system 500 in capturing 3D images of objects may be as follows. Firstly, the Lidar system 500 may be arranged or configured (or both) so that the objects whose 3D image is to be captured (referred to as targeted objects) are in a field of view (FOV) 510f of the Lidar system 500. The targeted objects may also be arranged (or moved) if possible so as to be in the FOV 510f of the Lidar system 500. For example, if the Lidar system 500 is used for capturing a 3D image of a person's face, then (A) the Lidar system 500 may be arranged or configured (or both) or (B) the person may move, or both (A) and (B), so that the person's face is in the FOV 510f and facing the Lidar system 500. It should be noted that all photons propagating in the FOV 510f and then into the optical system 510 are guided by the optical system 510 to the 12 APDs 350 of the image sensor 300.

In an embodiment, the FOV 510f may be 40° horizontal and 30° vertical. In other words, the FOV 510f has a shape of a right pyramid with its apex being the Lidar system 500 (or the optical system 510, to be more specific) and its base 510b being a rectangle at a very large distance from the apex (or at infinity for simplicity). Because the optical system 510 is considered the apex of the FOV 510f, the apex can be referred to as the apex 510.

In an embodiment, the FOV 510f may be deemed to include 12 sub-fields of view (sub-FOV) corresponding to the 12 APDs 350 of the image sensor 300 such that all photons propagating in a sub-FOV and then into the optical system 510 is guided by the optical system 510 to the corresponding APD 350. Specifically, the base 510b of the FOV 510f may be divided into 12 base rectangles arranged in an array of 3 rows and 4 columns. Each base rectangle and the apex 510 form a subpyramid that represents a sub-FOV of the 12 sub-FOVs. For example, the base rectangle 510b.1 and the apex 510 form a subpyramid that represents the sub-FOV corresponding to the APD 350.1 (hereafter, this subpyramid, this sub-FOV, and this base rectangle use the same reference numeral 510b.1 for simplicity). As a result, all photons propagating in this sub-FOV 510b.1 and then into the optical system 510 are guided by the optical system 510 to the corresponding APD 350.1 of the image sensor 300.

In an embodiment, while the targeted objects are in the FOV 510f of the Lidar system 500, the radiation source 520 may emit a pulse (or flash or burst) 520′ of photons toward the targeted objects so as to illuminate these targeted objects.

Regarding the operation of the Lidar system 500 with respect to the APD 350.1, assume that the corresponding sub-FOV 510b.1 intersects a surface of a targeted object facing the Lidar system 500 via an object surface spot 540 (also referred to as a spot of the scene). Assume further that a photon of the pulse 520′ bounces off the object surface spot 540, returns to the Lidar system 500 (or the optical system 510 to be more specific), and is guided by the optical system 510 to the corresponding APD 350.1. As a result, this photon contributes to cause a spike (i.e., a sharp increase) in the number of charge carriers in the APD 350.1. The more photons of the pulse 520′ that bounce off the object surface spot 540 in the sub-FOV 510b.1, return to the Lidar system 500, and enter the APD 350.1, the larger the spike, and the more easily the spike may be detected by the electronics layer 120.

In an embodiment, the electronics layer 120 may be configured to (a) measure the time period (called the time-of-flight or TOF for short) from the time at which the pulse 520′ is emitted by the radiation source 520 to the time at which the spike in the number of charge carriers in the APD 350.1 occurs, and then (b) based on the measured TOF, determine the spot distance from the Lidar system 500 to the object surface spot 540. In an embodiment, the formula used to determine this spot distance is: D=½(c×TOF), where D is the spot distance and c is the speed of light in vacuum (around 3×10⁸ m/s). For example, if the measured TOF is 60 ns, then D=½(3×10⁸ m/s×60 ns)=9 m.

In an alternative embodiment, the spot distance may be expressed in terms of the time it would take light to propagate from the Lidar system 500 to the object surface spot 540. In this alternative embodiment, the formula used to determine this spot distance is: D=½ TOF. For example, if the measured TOF is 60 ns, then D=½(60 ns)=30 ns.

In an embodiment, the operation of the Lidar system 500 with respect to the other 11 APDs 350 are similar to the operation of the Lidar system 500 with respect to the APD 350.1 as described above. As a result, in total, the Lidar system 500 determines 12 spot distances from the Lidar system 500 to 12 object surface spots in the 12 sub-FOVs. These 12 spot distances include the one spot distance from the Lidar system 500 to the object surface spot 540 in the sub-FOV 510b.1 described above. These 12 spot distances constitute a 3D image of the targeted objects in the FOV 510f. In other words, by determining the 12 spot distances as described above, the Lidar system 500 has captured a 3D image of the targeted objects in the FOV 510f. This 3D image of the targeted objects may be deemed to have 12 image pixels arranged in a rectangular array of 3 rows and 4 columns, wherein the 12 image pixels contain the 12 spot distances mentioned above.

In summary, the operation of the Lidar system 500 starts with making sure that the targeted objects are in the FOV 510f of the Lidar system 500. Next, the radiation source 520 emits the pulse 520′ of photons towards the targeted objects thereby illuminating these targeted objects. Photons of the pulse 520′ that bounce off surfaces of the targeted objects and return to the Lidar system 500 are guided by the optical system 510 to the 12 APDs 350 of the image sensor 300. These return photons create 12 spikes in the numbers of charge carriers in the 12 APDs 350. For each APD 350, by first measuring the time of flight TOF from the time at which the pulse 520′ is emitted by the radiation source 520 to the time at which the corresponding spike occurs in the APD 350, the electronics layer 120 can then determine the spot distance from the Lidar system 500 to the corresponding object surface spot corresponding the APD 350. By determining the 12 spot distances from the Lidar system 500 to the 12 corresponding object surface spots in the 12 corresponding sub-FOVs, the Lidar system 500 captures a 3D image of the targeted objects in the FOV 510f.

In an embodiment, the pulse 520′ of photons includes infrared photons. Because infrared photons are safe for human eyes, the Lidar system 500 may be safely used in applications that usually have people near the Lidar system 500 (e.g., self-driving cars, facial image capturing, etc.). It should be noted that silicon is not good in absorbing incident infrared photons (i.e., Si allows infrared photons to pass essentially without absorption). As a result, the electric signals (or charge carriers) created in silicon absorption regions of a typical image sensor of the prior art are rather weak and therefore may be obscured by electrical noise within the typical image sensor. In contrast, the APDs 350 of the present disclosure, even if being made of silicon, through the avalanche effect, significantly amplify the electrical signals which incident infrared photons create in the silicon absorption regions 310. As a result, these amplified electrical signals (i.e., the spikes mentioned above) may be easily detected by the electronics layer 120. This means that the Lidar system 500 which comprises mostly silicon is functional. Because Si is a reasonably cheap semiconductor material, the Lidar system 500 which comprises mostly silicon is reasonably cheap to make.

In the embodiments described above, the image sensor 300 includes 12 APDs 350. In general, the image sensor 300 may include N APDs 350 (N being a positive integer) arranged in any way (i.e., not necessarily in a rectangular array as described above). The more APDs 350 the image sensor 300 has, the higher spatial distance resolution the captured 3D image has. With N>1 as described above, the Lidar system 500 is usually referred to as a Flash Lidar system.

For the case N=1, the image sensor 300 has only 1 APD 350. In this case, in an embodiment, the FOV 510f may be narrowed down such that the FOV 510f is, for example, 1° horizontal and 1° vertical. Accordingly, the pulse 520′ of photons may be focused on the narrow FOV 510f and would look like a narrow beam that illuminates essentially only the targeted objects in the narrow FOV 510f. An advantage of this case (N=1) is that because the power of the pulse 520′ of photons is focused on the narrow FOV 510f, the Lidar system 500 may capture a 3D image of targeted objects farther away from the Lidar system 500. For example, the Lidar system 500 of this case (N=1) may be mounted on a flying airplane to capture 3D images of the ground below in sequence while the FOV 510f scans the ground (i.e., the FOV 510f is directed at a new spot of the scene before the Lidar system 500 captures a new 3D image).

In the embodiments described above, the electronic system of the electronics layer 120 of the image sensor 300 includes all the electronics components needed for TOF measurements and spot distance determinations. In an alternative embodiment, the Lidar system 500 further includes a separate signal processor (or even a computer) electrically connected to the image sensor 300 and the radiation source 520 such that both the electronic system of the electronics layer 120 and the signal processor may work together to handle the TOF measurements and spot distance determinations. As a result, in this alternative embodiment, the electronics layer 120 of the image sensor 300 does not have to include all the electronics needed for the TOF measurements and spot distance calculations, and therefore may be fabricated more easily.

In an embodiment, after capturing the 3D image of the targeted objects as described above, the Lidar system 500 may be used for capturing more 3D images in a similar manner. Specifically, if the Lidar system 500 is mounted on a self-driving car to monitor surrounding objects, then before each 3D image is captured, the Lidar system 500 may be arranged or configured (or both) so that the FOV 510f is directed at a new scene. For example, the Lidar system 500 (or the FOV 510f, to be more specific) may be rotated 40° around a vertical axis going through the Lidar system 500 before each new 3D image is captured. As a result, 9 3D images are captured for each revolution of 360° scene surrounding the self-driving car.

Alternatively, if the Lidar system 500 is used to monitor a room for intruders, then the FOV 510f of the Lidar system 500 may remain stationary with respect to the room while the Lidar system 500 captures 3D images of the room objects in the FOV 510f in sequence (i.e., captures one 3D image after another).

Next, in an embodiment, the Lidar system 500 may be configured to compare a first 3D image captured by the Lidar system 500 at a first time point with a second 3D image captured by the Lidar system 500 at a second time point, wherein the second time point is Td seconds after the first time point. For example, Td may be chosen to be 10 seconds to make it unlikely that the intruder's image in the first 3D image overlaps the intruder's image in the second 3D image when the first and second 3D images are superimposed on each other.

More specifically, in an embodiment, the comparison of the first and second 3D images may include determining the difference between the first and second 3D images as follows. A range change image of size 3×4 representing the difference between the first and second 3D images may be obtained by subtracting the second 3D image from the first 3D image. Specifically, assume the first 3D image includes 12 spot distances D1(i), i=1, . . . , 12, and the second 3D image includes 12 spot distances D2(i), i=1, . . . , 12, then the range change image includes 12 range changes RC(i), i=1, . . . , 12 wherein for i=1, . . . , 12, the range change RC(i)=D1(i)−D2(i).

Next, in an embodiment, based on the range change image obtained as described above, the Lidar system 500 may be configured to identify the suspicious pixel positions of the 3×4 array of 12 pixel positions that experience changes when the first and second 3D images are compared. Specifically, based on the range change image, the Lidar system 500 may be configured to obtain a Boolean image of size 3×4 including 12 Boolean image pixels (i), i=1, . . . , 12 as follows. For i=1, . . . , 12, if the absolute value of RC(i) exceeds a positive threshold value pre-specified by the user of the Lidar system 500, then the Boolean image pixel (i) of the Boolean image is set to TRUE. Otherwise, the Boolean image pixel (i) of the Boolean image is set to FALSE. It should be noted that the TRUE Boolean image pixels identify the suspicious pixel positions.

Next, in an embodiment, the Lidar system 500 may be configured to apply an algorithm on the suspicious pixel positions identified as described above to determine whether these suspicious pixel positions collectively have a size and shape of a human body in the 3×4 array of the 12 pixel positions. If the answer is yes, then the Lidar system 500 may be configured to trigger a security alarm system to indicate that an intruder is likely in the room.

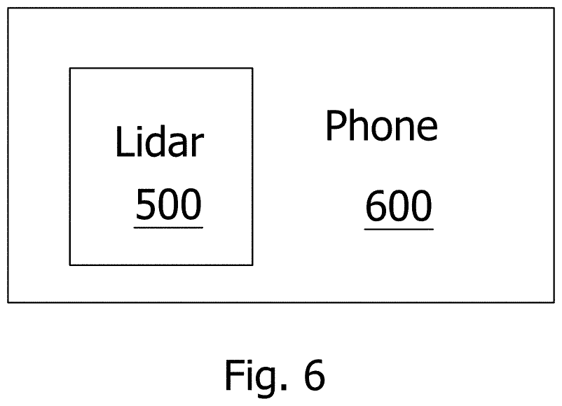

FIG. 6 schematically shows a phone 600 including the Lidar system 500, according to an embodiment. In an embodiment, the phone 600 may be configured to convert sounds (including voices) to electrical signals. In an embodiment, the phone 600 may be configured to reproduce sounds from such electrical signals which the phone 600 receives from another phone or device. In an embodiment, the phone 600 may be configured to send such electrical signals to another phone or device via wire, radio signal, the internet, electromagnetic wave, or any combinations thereof. In an embodiment, the phone 600 may be configured to receive such electrical signals from another phone or device via wire, radio signal, the internet, electromagnetic wave, or any combinations thereof. In an embodiment, the phone 600 may be configured to browse the Web (i.e., World Wide Web).

In an embodiment, the Lidar system 500 of the phone 600 may be used to capture a 3D range image of objects or scenes. In an embodiment, the Lidar system 500 of the phone 600 may be used to capture multiple 3D range images in sequence (i.e., capture 3D videos). In other words, the phone 600 may be used to capture 3D videos of spatial distance distribution of the surrounding scenes.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. A method of operating a phone comprising a Lidar system which comprises (a) an image sensor comprising an array of avalanche photodiodes (APDs)(i), i=1, . . . , N, N being a positive integer, for i=1, . . . , N, the APD (i) comprising an absorption region (i) and an amplification region (i), wherein the absorption region (i) is configured to generate charge carriers from a photon absorbed by the absorption region (i), wherein the amplification region (i) comprises a junction (i) with a junction electric field (i) in the junction (i), wherein the junction electric field (i) is at a value sufficient to cause an avalanche of charge carriers entering the amplification region (i), but not sufficient to make the avalanche self-sustaining, and wherein the junctions (i), i=1, . . . , N are discrete, and (b) a radiation source, the method comprising:
emitting a pulse of illumination photons at a time point Ta using the radiation source;
for i=1, . . . , N, measuring a time of flight (i) from Ta to a time point Tb(i) at which a photon of the illumination photons returns to the APD (i) after bouncing off an object surface spot (i) in a sub-field of view (i) of the Lidar system corresponding to the APD (i); and
for i=1, . . . , N, determining a spot distance (i) from the Lidar system to the object surface spot (i) based on the time of flight (i),
wherein the phone is configured to convert sounds to electrical signals,
wherein the phone is configured to reproduce sounds from electrical signals,
wherein the phone is configured to send electrical signals to another phone via wire, radio signal, the internet, electromagnetic wave, or any combinations thereof, and
wherein the phone is configured to receive electrical signals from another phone via wire, radio signal, the internet, electromagnetic wave, or any combinations thereof.

23. The method of claim 22, further comprising performing said emitting, said measuring, and said determining multiple times thereby capturing a video of spatial distance distribution of surrounding scenes.

24. (canceled)

25. The method of claim 22, wherein N is greater than 1.

26. The method of claim 22,
wherein the illumination photons comprise infrared photons, and
wherein, for i=1, . . . , N, the APD (i) comprises silicon.

27. (canceled)

28. The method of claim 22, wherein for i=1, . . . , N, an absorption region electric field (i) in the absorption region (i) is not high enough to cause avalanche effect in the absorption region (i).

29. The method of claim 22, wherein for i=1, . . . , N, the absorption region (i) is an intrinsic semiconductor or a semiconductor with a doping level less than 10¹² dopants/cm³.

30. The method of claim 22,
wherein N>1, and
wherein at least some absorption regions of the absorption regions (i), i=1, . . . , N are joined together.

31. The method of claim 22, wherein for i=1, . . . , N, the APD (i) further comprises an amplification region (i′) such that the amplification region (i) and the amplification region (i′) are on opposite sides of the absorption region (i).

32. The method of claim 22, wherein the amplification regions (i), i=1, . . . , N are discrete.

33. The method of claim 22, wherein for i=1, . . . , N, the junction (i) is a p-n junction or a heterojunction.

34. The method of claim 22,
wherein for i=1, . . . , N, the junction (i) comprises a first layer (i) and a second layer (i), and
wherein for i=1, . . . , N, the first layer (i) is a doped semiconductor and the second layer (i) is a heavily doped semiconductor.

35. The method of claim 34,
wherein for i=1, . . . , N, the junction (i) further comprises a third layer (i) sandwiched between the first layer (i) and the second layer (i), and
wherein for i=1, . . . , N, the third layer (i) comprises an intrinsic semiconductor.

36. The method of claim 35,
wherein N>1, and
wherein at least some third layers of the third layers (i), i=1, . . . , N, are joined together.

37. The method of claim 34, wherein for i=1, . . . , N, the first layer (i) has a doping level of 10¹³ to 10¹⁷ dopants/cm³.

38. The method of claim 34,
wherein N>1, and
wherein at least some first layers of the first layers (i), i=1, . . . , N are joined together.

39. The method of claim 34, wherein the image sensor further comprises electrodes (i), i=1, . . . , N in electrical contact with the second layers (i), i=1, . . . , N, respectively.

40. The method of claim 22, wherein the image sensor further comprises a passivation material configured to passivate a surface of the absorption regions (i), i=1, . . . , N.

41. The method of claim 22, wherein the image sensor further comprises a common electrode electrically connected to the absorption regions (i), i=1, . . . , N.

42. The method of claim 22, wherein for i=1, . . . , N, the junction (i) is separated from a junction of a neighbor junction by (a) a material of the absorption region (i), (b) a material of the first layer (i) or of the second layer (i), (c) an insulator material, or (d) a guard ring (i) of a doped semiconductor.

43. The method of claim 42,
wherein for i=1, . . . , N, the guard ring (i) is a doped semiconductor of a same doping type as the second layer (i), and
wherein for i=1, . . . , N, the guard ring (i) is not heavily doped.
